(19) United States
(12) Patent Application Publication
(10) Pub. No.: US 2021/0166827 A1
(43) Pub. Date: Jun. 3, 2021

(54) APPARATUS FOR EXPRESSING AND UTILIZING INTELLIGENT GENERAL ARRANGEMENT DRAWING OF ATOMIC POWER PLANT

(71) Applicant: KOREA HYDRO & NUCLEAR POWER CO., LTD, Gyeongsangbuk-do (KR)

(72) Inventors: Byung Ki Lim, Daejeon (KR); Byeong Suk Moon, Daejeon (KR); You Jin Park, Daejeon (KR)

(21) Appl. No.: 17/263,307

(22) PCT Filed: Nov. 1, 2018
(86) PCT No.: PCT/KR2018/013180

§ 371 Date: Jan. 26, 2021

(30) Foreign Application Priority Data
Aug. 10, 2018 (KR) 10-2018-0093789

(51) Int. Cl. G21D 1/02; G06F 30/13

(52) U.S. Cl. CPC G21D 1/02; G06F 30/13

(57) ABSTRACT

Disclosed is an apparatus for providing an intelligent general arrangement (GA) drawing of an atomic power plant. The apparatus comprises an intelligent GA drawing utilization unit for providing additional information on an equipment included in a particular level of a particular building of the atomic power plant, on the basis of an intelligent GA drawing in response to an user's input.

### TECHNICAL FIELD

The present disclosure relates to a general arrangement (GA) drawing of an atomic power plant and, more particularly, to an apparatus for expressing a general arrangement (GA) drawing of an atomic power plant as an intelligent general arrangement (GA) drawing and for using the intelligent general arrangement (GA) drawing.

### BACKGROUND ART

A general arrangement (GA) drawing that is used in the processes of design, construction, and O&M of an atomic power plant may be defined as a drawing that shows the positions of structures, systems, and machines for every level and building of the atomic power plant, that is, a general arrangement drawing.

The configuration of a GA drawing is composed of the positions of machines, the names of machines, the list of machines, and corresponding coordinates in corresponding levels and corresponding rooms of corresponding buildings where there is power plant equipment such as HVAC, electrical, instrumental, and mechanical equipment.

In particular, the general arrangement (GA) drawing of an atomic power plant is one of the important drawings that are used for examination of design, search of equipment positions, pre-simulation before logging of an operator, study of machine positions for new workers due to a design change in the construction process, and an equipment change during operation of the atomic power plant.

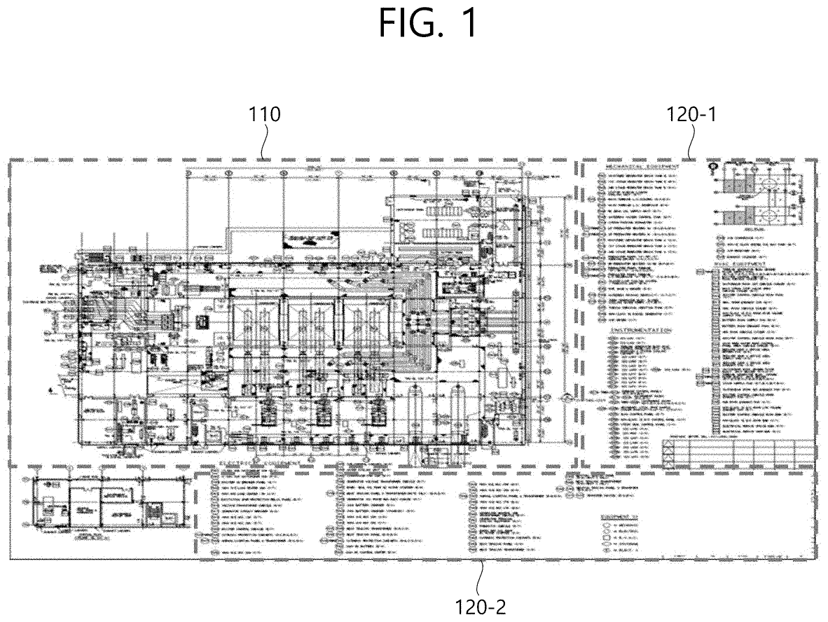

Since the list and positions of many power generation equipment in the levels and rooms of corresponding buildings are shown in the GA drawing, there is a limitation that it takes a user to search for corresponding machines in the GA drawing and legibility of the drawing is deteriorated. FIG. 1 is a machine arrangement drawing of a turbine building of an atomic power plant, which is one of GA drawings that are used in atomic power plants. As shown in FIG. 1, a GA drawing may be divided into a figure section 110 and equipment information sections 120-1 and 120-2.

All GA drawings for every corresponding area and position such as nuclear reactor buildings and containment buildings are managed by an enterprise resource planning system in the type of image documents for the drawing numbers, and if necessary, corresponding drawings are searched and used.

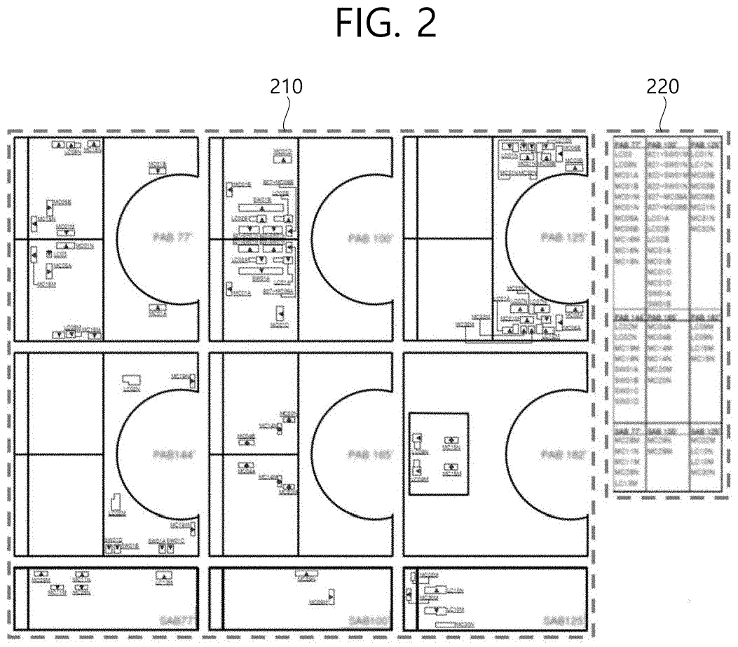

Further, machines that are frequently used during commissioning and operating of an atomic power plant such as the positions of a breaker and a valve that have the concepts of coordinates and a space are separately constructed in Hangeul or PDF files and used for the work of operators. FIG. 2 is a view showing the positions of breakers according to buildings and levels in a power plant. This may also be divided into a figure section 210 and an equipment information section 220. FIG. 2 shows an example of separately constructing and using the positions of breakers required for power supply of the equipment of an atomic power plant.

That is, general arrangement drawings are widely used for operation of an atomic power plant in the related art, but the drawings have a large amount of information in the drawing generated for each building and level and it is difficult to find out desired information from the large amount of information.

### DISCLOSURE

### Technical Problem

In order to solve the problems described above, an object of the present disclosure is to provide an apparatus for providing an intelligent GA drawing of an atomic power plant, the apparatus being able to change a GA drawing provided in relation to operation of an atomic power plant in the related art into an intelligent GA drawing so that individual machines are easily searched, and being able to maximize the usability of the GA drawing by adding additional functions such as search path setting and simulation for the workers of a power plant.

In order to solve the problems described above, another object of the present disclosure is to provide an apparatus for providing an intelligent GA drawing of an atomic power plant, the apparatus being able to improve workability of users by increasing efficiency and convenience for the user when the user uses a GA drawing by adding information and connecting relevant information without constructing a GA drawing into separate Hangeul or PDF files.

However, the objects of the present disclosure are not limited to those described above and may be expanded in various ways without departing from the spirit and scope of the present disclosure.

### Technical Solution

In order to achieve the objects of the present disclosure, an apparatus for providing an intelligent GA (General Arrangement) drawing of an atomic power plant includes: a GA drawing storage unit configured to store at least one or more GA drawings of an image type for a specific level of a specific building of the atomic power plant; an intelligent GA drawing generation unit configured to generate an intelligent GA drawing in which one or more equipment included in the Image-type GA drawing are objectified to be able to be discriminated and information about equipment are stored in a database, on the basis of the Image-type GA drawing; an input unit configured to receive input for generation or utilization of the intelligent GA drawing from a user; an intelligent GA drawing utilization unit configured to provide additional information about equipment included in a specific level of a specific building of the atomic power plant on the basis of the intelligent GA drawing in response to input about utilization of the user; and an output unit configured to display the additional information such that the user can recognize the additional information.

According to an aspect, the intelligent GA drawing generation unit may include: an object converter configured to recognize a figure of a first equipment displayed in a figure section of the image-type GA drawing and to designate a first ID to the recognized first equipment, and to generate information of a text type by recognizing information about the first equipment included in an equipment information section of the image-type GA drawing; and a data processor configured to connect and store the first ID of the first equipment, information about the region where the figure of the first equipment is positioned in the image-type GA drawing, and the text-type information of the first equipment.

According to an aspect, the object converter may recognize the figure of the first facility in response to selection of the figure region of the first facility by a user through the input unit.

According to an aspect, the object converter may convert the information about the first facility into text-type information by recognizing, as characters, the image of the portion about the information of the first facility in the facility information section of the image-type GA drawing.

According to an aspect, the intelligent GA drawing generation unit may further include a form processor configured to generate additional information about an equipment included in a specific level of a specific building of the atomic power plant provided by the GA drawing utilization unit, and the additional information about an equipment included in a specific level of a specific building of the atomic power plant may include information about a movement path of an operator or a worker according to the arrangement of equipments recognized in the specific level.

According to an aspect, the form processor may display a drawing tool button on the output unit and may generate information about the movement path of an operator or a worker in response to a movement path input in accordance with operation of the drawing tool button by a user through the input unit.

According to an aspect, the form processor may generate information about a plurality of movement paths of operators or workers and the intelligent GA drawing generation unit may display a movement path having the shortest distance of the plurality of movement paths of operators or workers on a display unit by receiving an instruction to select a shortest path through the input unit.

According to an aspect, the intelligent GA drawing utilization unit may be configured to change the display position of an intelligent GA drawing displayed on the output unit in response to selection of a specific point by a user through the input unit.

According to an aspect, the intelligent GA drawing utilization unit may be configured to display the intelligent GA drawing and a user-defined coordinate system on the output unit in response to a display instruction by a user through the input unit and to display a region of an intelligent GA drawing corresponding to user-defined coordinates on the output unit in response to input of user-defined coordinates by the user through the input unit.

According to an aspect, the apparatus may further include a relevant-information storage unit configured to store information about at least one of pictures, videos, and equipment manuals of one or more equipments included in an image-type GA drawing, in which the intelligent GA drawing utilization unit may be configured to display relevant information about an equipment on the display unit in response to selection of the equipment by a user through the input unit.

According to an aspect, the apparatus may further include a connection unit configured to receive a P&ID system drawing related to one or more equipments included in an image-type GA drawing from a basic system server of the atomic power plant, in which the intelligent GA drawing utilization unit may be configured to display the P&ID system drawing related to an equipment on the display unit in response to selection of the equipment by a user through the input unit.

According to an aspect, the intelligent GA drawing generation unit may further include a customizer configured to connect an intelligent GA drawing to an additional information drawing for the work of a first user in response to input by a user through the input unit such that the intelligent GA drawing provides information related to the work of the first user, in which the intelligent GA drawing utilization unit may display the additional information drawing on the output unit in response to an instruction to display an additional drawing by a user through the input unit.

According to an aspect, the additional information drawing may include a list and position information of breakers or valves positioned at a specific level of a specific building of the atomic power plant indicated by an intelligent GA drawing.

### [Advantageous Effects]

The present disclosure can have the following effects. However, a specific embodiment is not intended to have to include all of the following effects or only the following effects, so the scope of a right of the present disclosure should not be construed as being limited by the embodiment.

According to the apparatus for providing an intelligent GA drawing of an atomic power plant of an embodiment of the present disclosure, it is possible to improve the ability of searching for machine positions, determine positions in advance before visiting a site, and increase work usability such as a shunting drill in an emergency such as a fire, and train new employees by objectifying equipment positions and machine positions for an equipment list for each building and each level included in a GA drawing used in an atomic power plant and by storing relevant information in a database.

Further, the intelligent GA drawing can connect corresponding machine equipments to relevant drawings such as P&ID and can automatically check corresponding drawings by automatically cooperating with the enterprise resource planning system, whereby it is possible to provide information in real time and reduce time for searching drawings.

Further, since it is possible to search single integrated equipment information for a GA drawing, it is possible to improve maintenance of equipments, safe operation, and reliability.

Further, since a power plant map is constructed for complicated facilities in an atomic power plant, it is possible to search for a shortest path, set a work path, and compare paths, which can be used for other works such as training new employees, training operators, and setting an optimal path for monitoring equipments in the site.

Further, since the document-based GA drawing of the related art is converted into an intelligent GA drawing, it is possible to more realistically express equipments in cooperation of pictures, videos, etc. of corresponding equipment and it is possible to connect or add a valve position drawing for each room and a position drawing for each breaker load, which are used by operators, etc., to the intelligent GA drawing to be fit to the purpose of users.

Meanwhile, it is possible to customize an intelligent GA drawing utilization system to fit the object and the contents of personal work by storing it in a personal PC, so it is possible to secure convenience for a user.

### ADVANTAGEOUS EFFECTS

FIG. 1 is a machine arrangement drawing of a turbine building of an atomic power plant.

FIG. 2 is a view showing the positions of breakers according to buildings and levels in a power plant.

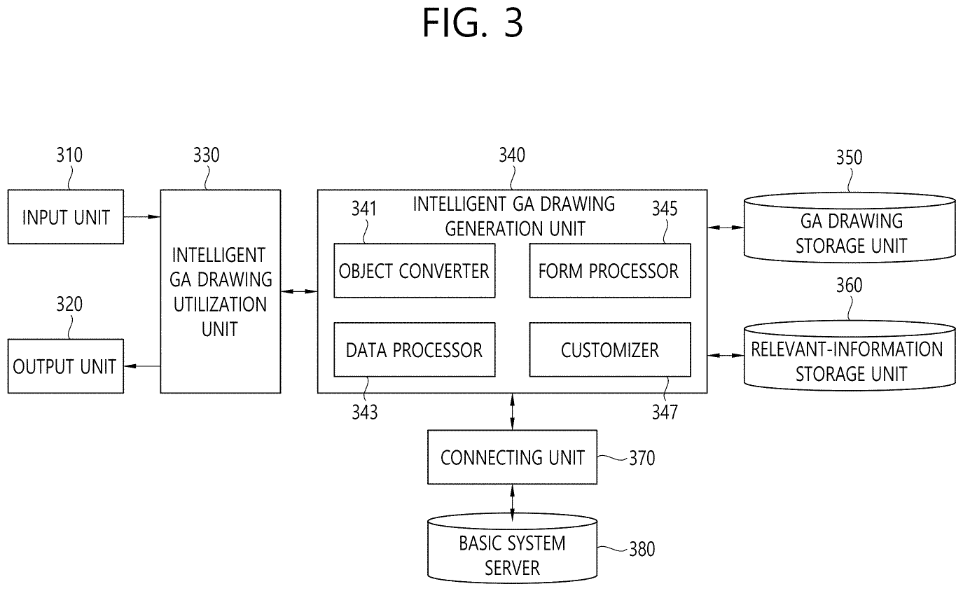

FIG. 3 is a block diagram showing the configuration of an apparatus for providing an intelligent GA drawing of an atomic power plant according to an embodiment of the present disclosure.

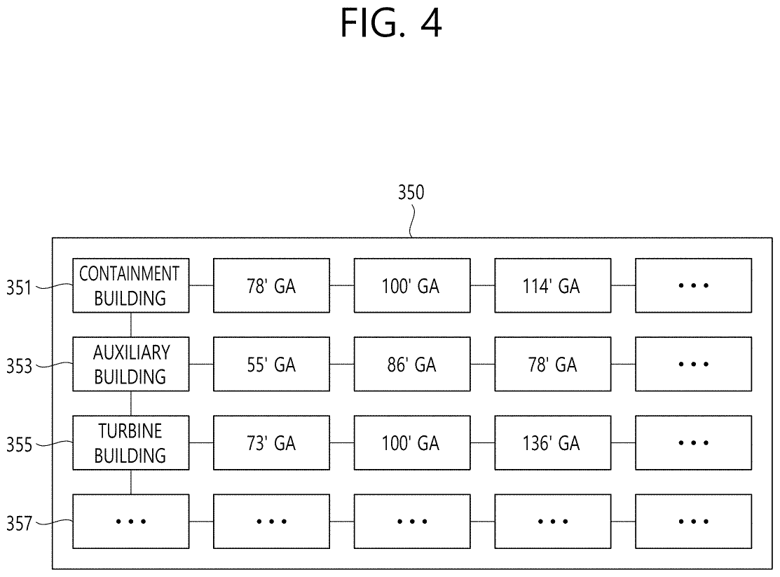

FIG. 4 is an exemplary view of a GA drawing storage unit of FIG. 3.

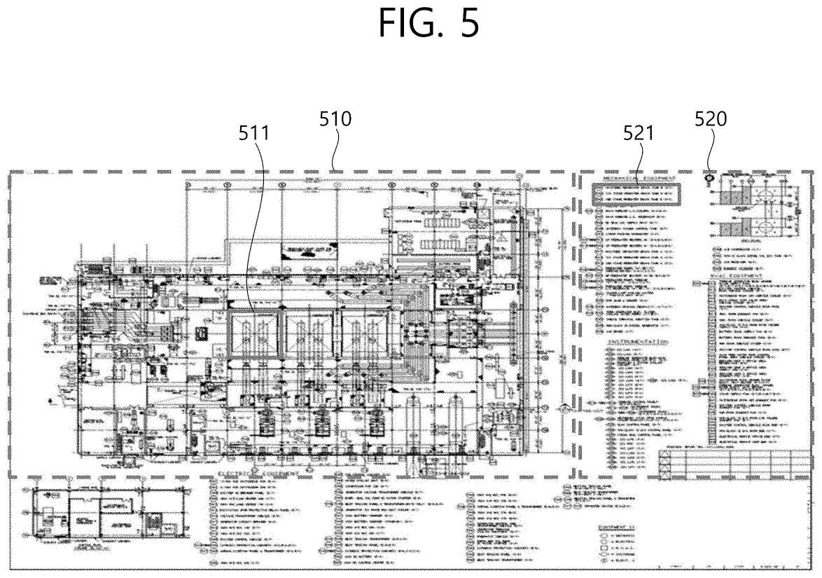

FIG. 5 is an exemplary view of a process according to an object converter and a data processor of FIG. 3.

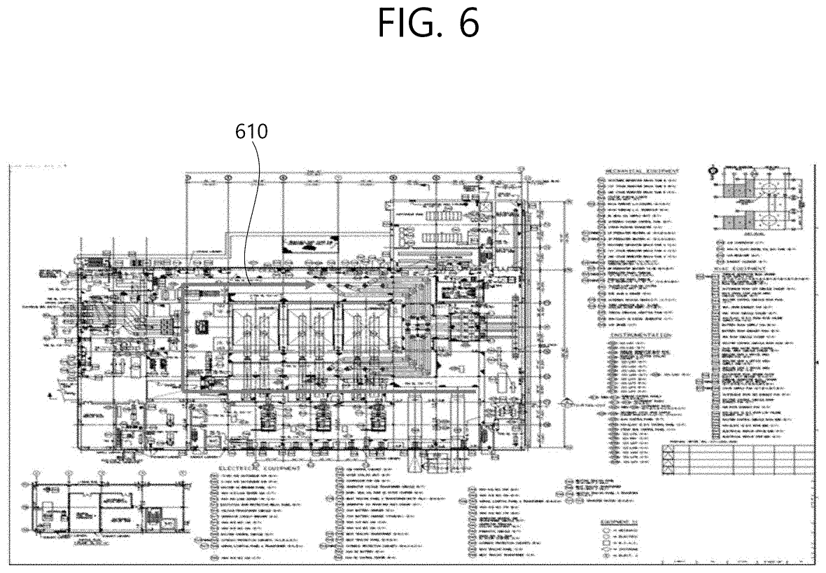

FIG. 6 is an exemplary view of a process according to a form processor of FIG. 3.

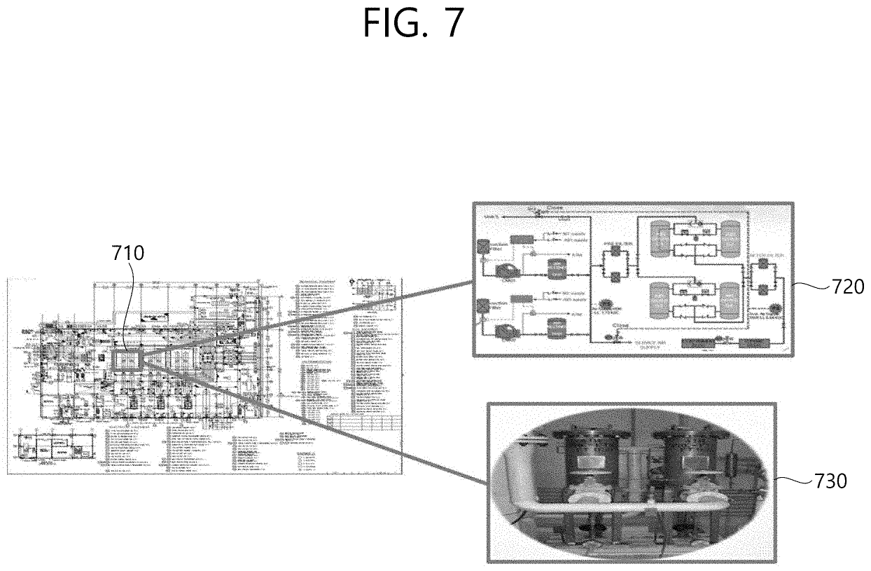

FIG. 7 is an exemplary view of a process according to a connection unit and a relevant-information storage unit of FIG. 3.

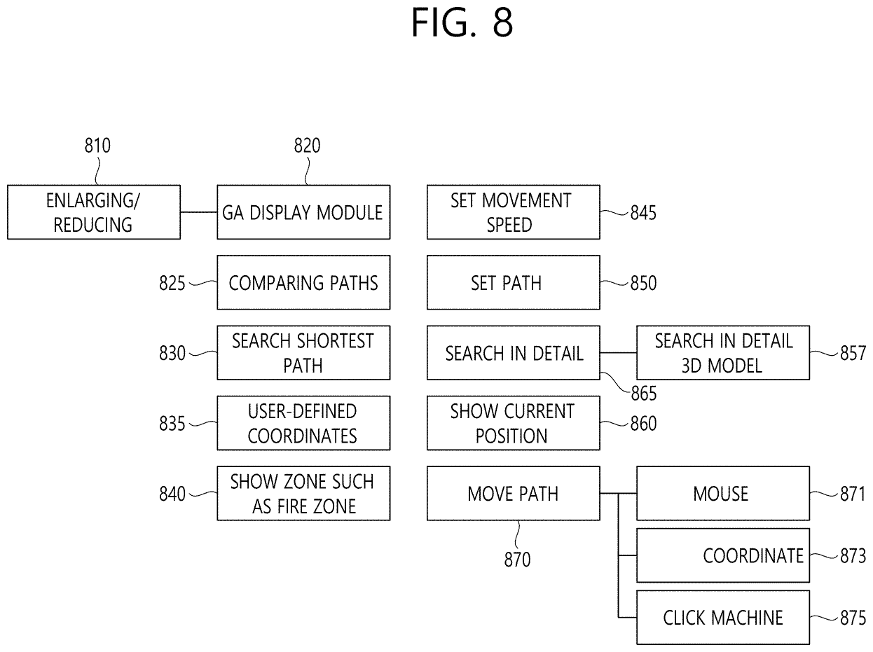

FIG. 8 is an exemplary view of a process according to an intelligent GA drawing utilization unit of FIG. 3.

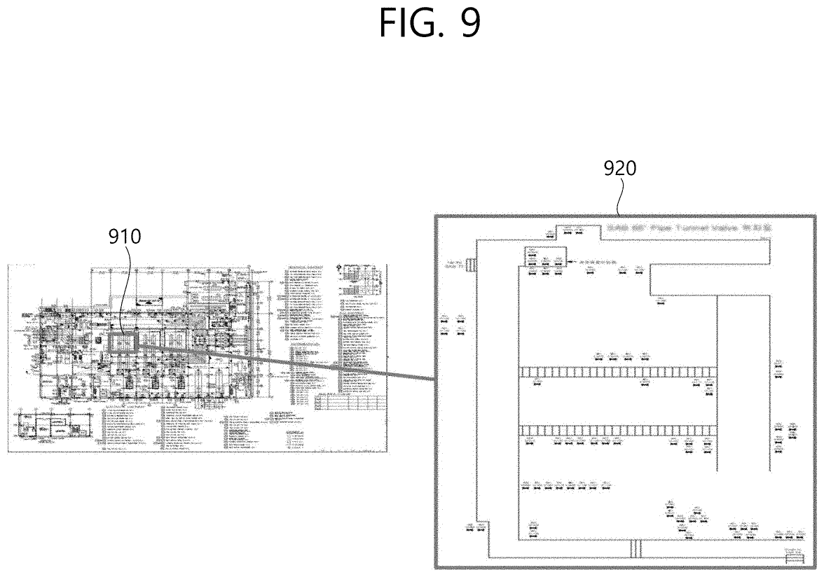

FIG. 9 is an exemplary view of a process according to a customizer of FIG. 3.

### MODE FOR DISCLOSURE

The present disclosure may be modified in various ways and implemented by various exemplary embodiments, so that specific exemplary embodiments are shown in the drawings and will be described in detail.

However, it is to be understood that the present disclosure is not limited to the specific exemplary embodiments, but includes all modifications, equivalents, and substitutions included in the spirit and the scope of the present disclosure.

Terms used in the specification, “first”, “second”, etc., may be used to describe various components, but the components are not to be construed as being limited to the terms. The terms are used only to distinguish one component from another component. For example, the “first” component may be named the “second” component, and vice versa, without departing from the scope of the present disclosure. The term “and/or” includes a combination of a plurality of relevant items or any one of a plurality of relevant terms.

It is to be understood that when one element is referred to as being “connected to” or “coupled to” another element, it may be connected directly to or coupled directly to another element or be connected to or coupled to another element, having the other element intervening therebetween. On the other hand, it should to be understood that when one element is referred to as being “connected directly to” or “coupled directly to” another element, it may be connected to or coupled to another element without the other element intervening therebetween.

Terms used in the present specification are used only to describe specific exemplary embodiments rather than limiting the present disclosure. Singular forms are intended to include plural forms unless the context clearly indicates otherwise. It will be further understood that the terms “comprises” or “have” used in this specification, specify the presence of stated features, steps, operations, components, parts, or a combination thereof, but do not preclude the presence or addition of one or more other features, numerals, steps, operations, components, parts, or a combination thereof.

Unless defined otherwise, it is to be understood that all the terms used in the specification including technical and scientific terms have the same meaning as those that are understood by those who skilled in the art. It will be further understood that terms defined in dictionaries that are commonly used should be interpreted as having meanings that are consistent with their meanings in the context of the relevant art and will not be interpreted in an idealized or overly formal sense unless expressly so defined herein.

Hereinafter, exemplary embodiments of the present disclosure will be described in more detail with reference to the accompanying drawings. In order to facilitate the general understanding of the present disclosure in describing the present disclosure, through the accompanying drawings, the same reference numerals will be used to describe the same components and an overlapped description of the same components will be omitted.

As described above, an apparatus for providing an intelligent GA drawing of an atomic power plant according to an embodiment of the present disclosure can change a GA drawing provided in relation to operation of an atomic power plant in the related art into an intelligent GA drawing so that individual machines are easily searched, and can maximize the usability of the GA drawing by adding additional functions such as search path setting and simulation for the workers of a power plant. Further, the apparatus can improve workability of users by increasing efficiency and convenience for the user when the user uses a GA drawing by adding information and connecting relevant information without constructing a GA drawing into separate Hangeul or PDF files.

In detail, according to the apparatus for providing an intelligent GA drawing of an atomic power plant of an embodiment of the present disclosure, it is possible to change a GA drawing based on documents that are used in an atomic power plant into an intelligent GA drawing, that is, to change corresponding equipments included in a GA drawing into objects and to provide IDs. Further, it is possible to improve workability by connecting relevant information to corresponding equipments and simulating movement paths by making a list of machines into data and implementing a function for enabling workers, who use the GA drawing when designing, constructing, and operating an atomic power plant, to easily trace the equipments of the plant such as constructing movement paths for operators and workers.

Further, according to the apparatus for providing an intelligent GA drawing of an atomic power plant of an embodiment of the present disclosure, it is possible to timely provide information to users who use the intelligent GA drawing such as operators and managers of the atomic power plant by automatically inputting relevant information (pictures, drawings, relevant information, etc.) about corresponding equipments or performing customizing to fit connectable individual demands

Further, according to the apparatus for providing an intelligent GA drawing of an atomic power plant of an embodiment of the present disclosure, it is possible to timely provide accurate path information such as setting optimum paths, searching of comparative paths by constructing a movement path map, that is, a GA map for examining paths for examining equipments for operators, and setting movement spaces for workers from an objectified GA drawings required for constructing and operating an atomic power plant.

Further, according to the apparatus for providing an intelligent GA drawing of an atomic power plant of an embodiment of the present disclosure, it is possible to automatically connect pictures and/or 3D models of places corresponding to specific equipments and to enable users to easily input additional information even without using specific documents, pictures, and programs such as inputting breaker coordinates for corresponding equipments such as a breaker, if necessary, in order to compensate for the limitation of the 2D GA drawing for the positions of equipments in an atomic power plant.

Further, P&ID system drawings can be connected to corresponding machines, so it is possible to provide accurate and integral information about the positions and functions of corresponding equipments and to exclude a specific drawing search device.

FIG. 3 is a block diagram showing the configuration of an apparatus for providing an intelligent GA drawing of an atomic power plant according to an embodiment of the present disclosure. Hereafter, an apparatus for providing an intelligent GA drawing of an atomic power plant according to an embodiment of the present disclosure is described in more detail with reference to FIG. 3.

As shown in FIG. 1, an apparatus for providing an intelligent GA (general arrangement) drawing of an atomic power plant according to an embodiment of the present disclosure may include an input unit 310, an output unit 320, an intelligent GA drawing utilization unit 330, an intelligent GA drawing generation unit 340, a GA drawing storage unit 350, a relevant-information storage unit 360, and a connection unit 370. The apparatus for providing an intelligent GA drawing of an atomic power plant can transmit/receive information to/from a basic system server 380 through the connection unit 370.

The GA drawing storage unit 350 may be configured to store one or more GA drawings in an image type for a specific level in a specific building of an atomic power plant. The intelligent GA drawing generation unit 340 can generate an intelligent GA drawing in which one or more equipments included in the Image-type GA drawing are objectified to be able to be discriminated and information about equipments are stored in a database, on the basis of the Image-type GA drawing stored in the GA drawing storage unit. The input unit 310 receives input about creation of the intelligent GA drawing or input about utilization from a user and the intelligent GA drawing utilization unit 330 can provide additional information about equipments included in a specific level of a specific building of the atomic power plant on the basis of the intelligent GA drawing in response to input about utilization of the user. The output unit 320 is configured to display the additional information such that the user can recognize the additional information.

In more detail, FIG. 4 is an exemplary view of the GA drawing storage unit of FIG. 3. The GA drawing storage unit 350 may be configured to store one or more GA drawings in an image type for a specific level in a specific building of an atomic power plant. That is, the GA drawing storage unit 350 can function as a database DB integrally managing GA drawings, that is, the object of the present disclosure, and can store one or more GA drawings in an image type for each level of each of a containment building 351, an auxiliary building 353, a turbine building 355, and other buildings 357. The image-type GA drawings can be stored in the GA drawing storage unit 350 in the structure shown in FIG. 4.

Referring to FIG. 3 again, the intelligent GA drawing generation unit 340 can generate an intelligent GA drawing in which one or more equipments included in the Image-type GA drawing are objectified to be able to be discriminated and information about equipments are stored in a database, on the basis of the Image-type GA drawing. As shown in FIG. 3, the intelligent GA drawing generation unit 340 may include an object converter 341, a data processor 343, a form processor 345, and a customizer 347. The intelligent GA drawing generation unit 340 can convert it into data (object) generating equipment positions, etc., such as equipment and HVAC, which are components in a GA drawing constructed as a PDF file. That is, it is a device that can store contents corresponding to equipment, HVAC, etc. in a GA drawing into a database, if necessary, can generate and store additional data, and can be connected with a device for generating and converting data and an equipment machine form. The operation principle of a converting device that can implement a GA drawing constructed as a PDF file or a document file into data (object) in the related art is as follows. It is possible to perform objectification using a data converter or a data editor for converting corresponding equipments in a GA drawing into an intelligent type. That is, it may correspond to a data (object) converter using GA equipment information.

FIG. 5 is an exemplary view of a process according to an object converter 341 and a data processor 343 of FIG. 3. As shown in FIG. 5, the object converter 341 can recognize the FIG. 511 of a first equipment displayed in a figure section 4510 of an image-type GA drawing and can designate a first ID to the recognized first equipment, and can generate information of a text type by recognizing information 521 about the first equipment included in an equipment information section 520 of the image-type GA drawing. The data processor 343 can connect and store the first ID of the first equipment, information about the region where the figure of the first equipment is positioned in the image-type GA drawing, and the text-type information of the first equipment.

According to an aspect, the object converter 341 can recognize the figure of the first equipment in response to selection of the figure region of the first equipment by a user through the input unit 310. Further, according to an aspect, the object converter 341 can convert the information about the first equipment into text-type information by recognizing, as characters, the image of the portion about the information of the first equipment in the equipment information section of the image-type GA drawing.

As shown in FIG. 3, the intelligent GA drawing generation unit 340 may include the form processor 345 and the form processor 345 may be configured to generate additional information about an equipment included in a specific level of a specific building of the atomic power plant provided by the GA drawing utilization unit 330. In other words, the form processor 345 can extract a converted 2D GA drawing of the atomic power plant from a converter and can display movement paths in the atomic power plant, and may be configured to implement the function of the GA drawing utilization unit 330 that a user uses. Further, the form processor 345 can function as a plant map creation device using a drawing tool program and rendering tools for constructing movement paths for operators and workers of a GA drawing and a device that includes various utilities being able to editing a map and adding contents and implements a function of constructing functions that can be used in the intelligent GA drawing utilization unit 330 according to an embodiment of the present disclosure.

FIG. 6 is an exemplary view of a process according to the form processor of FIG. 3. Additional information about an equipment included in a specific level of a specific building of an atomic power plant, as shown in FIG. 6, may include information 610 about a movement path of an operator or a worker according to the arrangement of equipments recognized in the specific level.

According to an aspect, the form processor 345 can display a drawing tool button on the output unit 320 and can generate information about the movement path of an operator or a worker in response to a movement path input in accordance with operation of the drawing tool button by a user through the input unit 310. Further, the form processor 345 may be configured to generate information about a plurality of movement paths of operators or workers and the intelligent GA drawing generation unit 340 may be configured to display a movement path having the shortest distance of the plurality of movement paths of operators or workers on a display unit 320 by receiving an instruction to select the shortest path through the input unit 310.

As shown in FIG. 3, the apparatus for providing an intelligent GA drawing of an atomic power plant according to an embodiment of the present disclosure may include the relevant-information storage unit 360 and the connection unit 370.

The relevant-information storage unit 360 can store information about at least one of pictures, videos, and equipment manuals of one or more equipments included in an image-type GA drawing. The intelligent GA drawing utilization unit 330 may be configured to display relevant information about an equipment on the display unit 320 in response to selection of the equipment by a user through the input unit 310. The relevant-information storage unit 360 can store information required for a corresponding equipment such as a picture, a video, etc. of a site of a power plant equipment. Accordingly, the intelligent GA drawing according to an embodiment of the present disclosure can connect and manage pictures, videos, manuals of relevant machines, etc. of actual equipments and can immediately show corresponding contents after corresponding machines are clicked in order to compensate for the defects of GA drawings having a document form in the related art.

The connection unit 370 may be configured to receive a P&ID system drawing related to one or more equipments included in an image-type GA drawing from the basic system server 380 of the atomic power plant. The intelligent GA drawing utilization unit 330 may be configured to display a P&ID system drawing related to an equipment on the display unit 320 in response to selection of the equipment by a user through the input unit 310. The connection unit 370 can be connected with a data processor for inputting, changing, registering data of internal machines of power plant equipments using a data management tool or an enterprise resource planning system storing relevant information such as existing drawings. That is, it is possible to operate with the property of a basic system such as a P&ID and a corresponding 3D model in order to maximize the usability of an intelligent GA drawing.

FIG. 7 is an exemplary view of a process according to a connection unit and a relevant-information storage unit of FIG. 3. As shown in FIG. 7, according to an aspect of the present disclosure, a P&ID system drawing related to an equipment 710 included a GA drawing may be displayed on the output unit 320 or a relevant image information 730 stored in the relevant-information storage unit 360 may be displayed on the output unit 320 by the connection unit 370.

Referring to FIG. 3 again, the intelligent GA drawing utilization unit 330 may be configured to provide additional information about an equipment included in a specific level of a specific building of the atomic power plant on the basis of the intelligent GA drawing in response to input about utilization of a user. That is, the intelligent GA drawing utilization unit 330 can set a shortest path, set an equipment operation monitoring path, and set the position of a worker in order to effectively use a 2D-map of the atomic power plant using the GA drawing. In more detail, it is a device for a method that displays a plant 2D map showing the entire power plant in 2D and that is used by a user.

According to an aspect, the intelligent GA drawing utilization unit 330 may be configured to change the display position of an intelligent GA drawing displayed on the output unit 320 in response to selection of a specific point by a user through the input unit 310. Further, according to an aspect, the intelligent GA drawing utilization unit 330 may be configured to display the intelligent GA drawing and a user-defined coordinate system on the output unit 320 in response to a display instruction by a user through the input unit 310 and to display a region of an intelligent GA drawing corresponding to user-defined coordinates on the output unit 320 in response to input of user-defined coordinates by the user through the input unit 310.

FIG. 8 is an exemplary view of a process according to an intelligent GA drawing utilization unit of FIG. 3. According to the plant 2D map, it is possible to search for a shortest path, set a work path, and compare paths by applying an interactive application method. Further, it may have various connection functions such as moving a map image according to mouse input, displaying a user-defined coordinate system, moving a map by coordinates, setting a fire zone, moving a map by clicking a corresponding machine, moving a path, setting a movement speed, providing work path selection information, finding out the current position of a worker, enlarging, reducing, moving, displaying, projecting an analysis result connection plant coordinate system/model, searching property, and visualizing a 3D map using a method of displaying a corresponding position.

That is, as shown in FIG. 8, it is possible to perform enlarging/reducing for information output on the output unit 320 (810), comparing paths through a GA display module 820 (825), searching for a shortest path (830), implementing user-defined coordinates (835), and showing a zone such as a fire zone (840). Further, it is possible to perform searching a 3D model in detail (857) and showing the current position (860) by setting a movement speed (845), setting a path (850), and searching in detail (865), and to perform moving a path (870) through a mouse 871, coordinates 873, or click of a machine 875.

Referring to FIG. 3 again, the intelligent GA drawing generation unit 340 of the apparatus for providing an intelligent GA drawing of an atomic power plant according to an embodiment of the present disclosure may include the customizer 347. The customizer 347 may be configured as a personal customizer that can be customized in a user PC to be fit to personal work such as editing the position of breaker cabinet load for each corresponding position in GA and inputting a valve position drawing. In detail, it is possible to customize an intelligent GA drawing utilization system constructed by the utilization unit 330 according to an embodiment of the present disclosure to fit the object and the contents of personal work by storing it in a personal PC. In relation to this, FIG. 9 is an exemplary view of a process according to a customizer of FIG. 3. As shown in FIG. 9, for example, it may be possible to enable a user to add and change desired functions such as constructing a list of breakers or a list of valves in a specific area into a drawing file, a Word file, etc., and connecting the list to a machine position drawing. This makes it possible to secure convenience for a user by changing predetermined work to fit the characteristic of the user.

According to an aspect, the customizer 347 may be configured to connect an intelligent GA drawing to an additional information drawing for the work of a first user in response to input by a user through the input unit 310 such that the intelligent GA drawing provides information related to the work of the first user, in which the intelligent GA drawing utilization unit 330 can display the additional information drawing on the output unit 320 in response to an instruction to display an additional drawing by a user through the input unit 310. According to an aspect, the additional information drawing may include a list and position information 920 of breakers or valves for an equipment 910, for example, a breaker or a valve positioned at a specific level of a specific building of the atomic power plant indicated by an intelligent GA drawing.

The operation of the apparatus for providing an intelligent GA drawing of an atomic power plant according to the present disclosure may be controlled by computer-readable codes in a computer-readable recording medium. A computer-readable recording medium includes all kinds of recording media that keep data that can be decoded by a computer system. For example, there may be a ROM (Read Only Memory), a RAM(Random Access Memory), a magnetic tape, a magnetic disc, a flash memory, an optical data storage device, etc. Further, the computer-readable recording medium may be stored and executed as codes that are distributed in computer systems connected through a computer communication network and that can be read in a distribution type.

Although the present disclosure was described above with reference to drawings and the exemplary embodiments, it should be understood that the protective scope of the present disclosure is not limited to the drawings and the exemplary embodiments and the present disclosure may be changed and modified in various ways by those skilled in the art, without departing from the spirit and scope of the present disclosure described in claims.

In detail, the features described above can be executed in a digital electronic circuit, or computer hardware, firmware, or combinations thereof. The features may be executed by a computer program product that is implemented in a storage device in a machine-readable storage device, for example, for execution by a programmable processor. Further, the features can be performed by a programmable processor that executes a program of commands for performing functions of the described embodiments by operating and creating output in input data. The described features can be executed in one or more computer programs that can be executed in a programmable system including at least one programmable processor, at least one input device, and at least one output device combined to receive data and commands from a data storage system and to transmit data and commands to the data storage system. The computer program includes a set of commands that can be directly or indirectly used in a computer to perform specific operations for predetermined results. The computer program can be written in any one of programming languages including combined or analyzed languages and can be used in any type included as another unit suitable to be used in module, element, subroutine, or other computer environments or a program that can be independently operated.

Processors suitable for executing a program of commands, for example, include both of microprocessors for a common use or a specific use, and a single processor or multiple processors of different kinds of computers. Further, storage devices suitable for implementing computer program commands and data for implementing the described features, for example, include all types of nonvolatile memories including semiconductor memory devices such as an EPROM, an EEPROM, and a flash memory device, magnetic devices such as internal hard disks and removable discs, magneto-optical devices, and CD-Rom and DVD-ROM discs. Processors and memories may be integrated in ASICs ((application-specific integrated circuits) or may be added by ASICs.

It will be apparent to those skilled in the art that the foregoing present disclosure is described on the basis of a series of function blocks, but is not limited by the foregoing embodiments and the accompanying drawings, and various modifications and changes may be made without departing from the scope and spirit of the present disclosure.

Combinations of the embodiments described above are not limited to the embodiments described above and various types of combinations may be provided in addition to the embodiments described above in accordance with implementation and/or necessity.

In the embodiments described above, although methods are described on the basis of flowcharts including a series of steps or blocks, the present disclosure is not limited to the order of the steps and some steps may be generated in a different order as different steps or may be generated simultaneously. Further, those skilled in the art may understand that the steps included in the flowcharts are not exclusive and may be included in other steps, or one or more steps of the flowcharts may be removed without influencing the scope of the present disclosure.

The embodiments described above include various examples. Although it is difficult to describe all possible combinations for showing various examples, those skilled in the art may recognize that other combinations are possible. Accordingly, it should be understood that the present disclosure includes all other replacements, changes, and modifications included in the following claims.

1. An apparatus for providing an intelligent GA (General Arrangement) drawing of an atomic power plant, the apparatus comprising:
a GA drawing storage unit configured to store at least one or more GA drawings of an image type for a specific level of a specific building of the atomic power plant;
an intelligent GA drawing generation unit configured to generate an intelligent GA drawing in which one or more equipments included in the Image-type GA drawing are objectified to be able to be discriminated and information about equipments are stored in a database, on the basis of the Image-type GA drawing;
an input unit configured to receive input for generation or utilization of the intelligent GA drawing from a user;
an intelligent GA drawing utilization unit configured to provide additional information about equipments included in a specific level of a specific building of the atomic power plant on the basis of the intelligent GA drawing in response to input about utilization of the user; and
an output unit configured to display the additional information such that the user can recognize the additional information.

2. The apparatus of claim 1, wherein the intelligent GA drawing generation unit includes:
an object converter configured to recognize a figure of a first equipment displayed in a figure section of the image-type GA drawing and to designate a first ID to the recognized first equipment, and to generate information of a text type by recognizing information about the first equipment included in an equipment information section of the image-type GA drawing; and
a data processor configured to connect and store the first ID of the first equipment, information about the region where the figure of the first equipment is positioned in the image-type GA drawing, and the text-type information of the first equipment.

3. The apparatus of claim 1, wherein the object converter recognizes the figure of the first equipment in response to selection of the figure region of the first equipment by a user through the input unit.

4. The apparatus of claim 1, wherein the object converter converts the information about the first equipment into text-type information by recognizing, as characters, the image of the portion about the information of the first equipment in the equipment information section of the image-type GA drawing.

5. The apparatus of claim 2, wherein the intelligent GA drawing generation unit further includes a form processor configured to generate additional information about an equipment included in a specific level of a specific building of the atomic power plant provided by the GA drawing utilization unit, and
the additional information about an equipment included in a specific level of a specific building of the atomic power plant includes information about a movement path of an operator or a worker according to the arrangement of equipments recognized in the specific level.

6. The apparatus of claim 5, wherein the form processor displays a drawing tool button on the output unit and generates information about the movement path of an operator or a worker in response to a movement path input in accordance with operation of the drawing tool button by a user through the input unit.

7. The apparatus of claim 6, wherein the form processor generates information about a plurality of movement paths of operators or workers and the intelligent GA drawing generation unit displays a movement path having the shortest distance of the plurality of movement paths of operators or workers on a display unit by receiving an instruction to select a shortest path through the input unit.

8. The apparatus of claim 1, wherein the intelligent GA drawing utilization unit is configured to change the display position of an intelligent GA drawing displayed on the output unit in response to selection of a specific point by a user through the input unit.

9. The apparatus of claim 1, wherein the intelligent GA drawing utilization unit is configured to display the intelligent GA drawing and a user-defined coordinate system on the output unit in response to a display instruction by a user through the input unit and to display a region of an intelligent GA drawing corresponding to user-defined coordinates on the output unit in response to input of user-defined coordinates by the user through the input unit.

10. The apparatus of claim 1, further comprising a relevant-information storage unit configured to store information about at least one of pictures, videos, and equipment manuals of one or more equipments included in an image-type GA drawing,
wherein the intelligent GA drawing utilization unit is configured to display relevant information about an equipment on the display unit in response to selection of the equipment by a user through the input unit.

11. The apparatus of claim 10, further comprising a connection unit configured to receive a P&ID system drawing related to one or more equipments included in an image-type GA drawing from a basic system server of the atomic power plant,
wherein the intelligent GA drawing utilization unit is configured to display the P&ID system drawing related to an equipment on the display unit in response to selection of the equipment by a user through the input unit.

12. The apparatus of claim 1, wherein the intelligent GA drawing generation unit further includes a customizer configured to connect an intelligent GA drawing to an additional information drawing for the work of a first user in response to input by a user through the input unit such that the intelligent GA drawing provides information related to the work of the first user,
wherein the intelligent GA drawing utilization unit displays the additional information drawing on the output unit in response to an instruction to display an additional drawing by a user through the input unit.

13. The apparatus of claim 12, wherein the additional information drawing includes a list and position information of breakers or valves positioned at a specific level of a specific building of the atomic power plant indicated by an intelligent GA drawing.
